(19) United States
(12) Patent Application Publication
(10) Pub. No.: US 2009/0145634 A1
(43) Pub. Date: Jun. 11, 2009

(54) FLEXIBLE PRINTED CIRCUITBOARD WITH REINFORCEMENT STRUCTURE

(75) Inventor: FU-MIN HSU, Taichung County (TW)

Correspondence Address: WPAT, PC, 7225 BEVERLY ST., ANNANDALE, VA, 22003, US

(73) Assignee: WINTEK CORPORATION, Taichung County (TW)

(21) Appl. No.: 12/276,681

(22) Filed: Nov. 24, 2008

(30) Foreign Application Priority Data
Dec. 10, 2007 (TW) 096147072

(51) Int. Cl. H05K 1/00

(52) U.S. Cl. 174/254

(57) ABSTRACT

A flexible printed circuitboard (FPC) with reinforcement structure is disclosed, which comprises: a flexible printed circuitboard (FPC), configured with an extended part at a side thereof; and an a stiffener, stacking on a surface of the FPC on the area excepting the extended part while configuring a recess on the stiffener at the position thereof corresponding to the extending direction of the extended part. With the aforesaid structure, it can reduce the shear stress from concentrating at the joint between the extended part and the FPC and thus prevent the FPC from breaking so that the strength of the FPC can be enhanced.

### FIELD OF THE INVENTION

The present invention relates to a flexible printed circuitboard (FPC), and more particularly to a FPC configured with a reinforcement structure at a position thereof where stress is concentrating.

### BACKGROUND OF THE INVENTION

With rapid advance of technology and the improvement of our living quality, the designs for all kinds of consumer electronic products, including hand-held computers, palm-sized game consoles and smart phones, are becoming more and more diversified while their lifespan are shorten as well. Among all those innovated new designs, the so-called clam-shell or foldable design is most welcomed by consumers and thus becoming the main stream in the market. Moreover, almost all of those foldable electronic products adopt the design of configuring a flexible printed circuitboards (FPC) at their bending areas to be used for transmitting electric signals. As the FPC is flexible, light-weighted and thin, it is especially suitable for those consumer electronic products of moveable structures that are designed to be thinner, lighter and smaller.

It is noted that backlight module (BLM), being considered as the core for most liquid crystal display module (LCM) currently available, is vulnerable and easy to be damaged when it is handle carelessly during transportation or assembly. Thus, in each FPC used in any BLM, it is usually to arrange a stiffener on the FPC at the position corresponding to its light bar for reinforcing the FPC's strength. However, for those positions on the FPC that are designed to be bended, there can be no stiffeners being arranged thereon. Consequently, the thicknesses of the FPC at portions that are reinforced by stiffeners are different from those without stiffeners so that stresses are common to be seen concentrating at the interfaces between those of different thicknesses. The stress concentration is especially sever for those T-shaped parts that it often break or tear the T-shaped parts and thus cause circuit break that eventually cause the electronic device to malfunction, and consequently causes difficulty in product maintenance and cost-increase in after-sale service.

In FIG. 1, as the extended part 11 of a conventional FPC 10 is not reinforced by the use of a stiffener and thus the thicknesses at the interface between the FPC 10 and the extended part 11 are different, stress is going to concentrate at the interface when the extended part 11 or the FPC 10 is subjecting to an external force exerting tangential to the interface. The concentrating stress is going to cause the FPC 10 to break following the path C shown in FIG. 1 and thus causes the extended part 11 to snap and eventually separate from the FPC completely.

### SUMMARY OF THE INVENTION

In view of the disadvantages of prior art, the primary object of the present invention is to provide a reinforce structure capable of preventing stress from concentrating, by which not only the strength of light bar can be increase so as to protect the same from breaking, but also the reliability and security for connecting parts of a light bar to its FPC are enhanced.

To achieve the above object, the present invention provides a flexible printed circuitboard (FPC) with reinforcement structure, which comprises: a flexible printed circuitboard (FPC), configured with an extended part at a side thereof; and an a stiffener, stacking on a surface of the FPC on the area excepting the extended part while configuring a recess on the stiffener at the position thereof corresponding to the extending direction of the extended part.

By attaching a stiffener or a multi-layered plate to a FPC, the aforesaid FPC is able to maintain a specific rigidity not only for facilitating an assembly process to be performed, but also for enhancing the efficiency of a SMT process. In addition, by forming a recess on the FPC at position where stress is likely to concentrate, the recess is able to dissipate the stress in a manner that the stress can be distributed evenly through the whole FPC, and thus not only the strength of the FPC is enhanced, but also eventually the reliability of the electronic product manufactured from the FPC is increased.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic diagram showing a conventional FPC being broken by concentrating stress.

FIG. 2 is a schematic view of a FPC with reinforcement structure according to an exemplary embodiment of the invention.

FIG. 3 shows a variety of recess formed on a FPC of the invention.

FIG. 4 shows a variety of chamfer design used in a FPC of the invention.

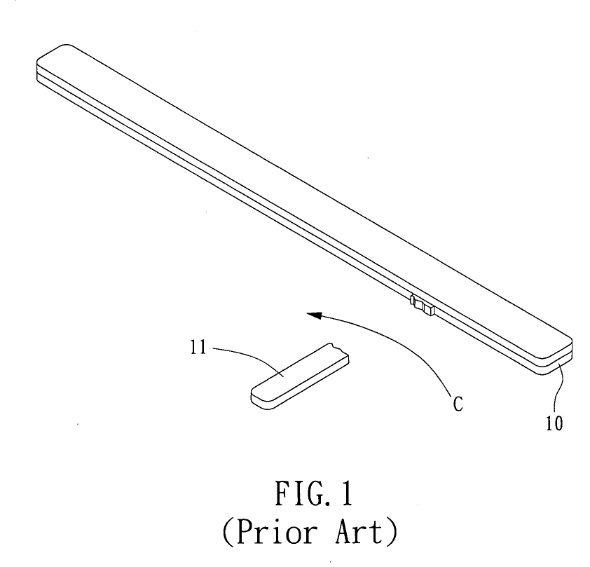

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

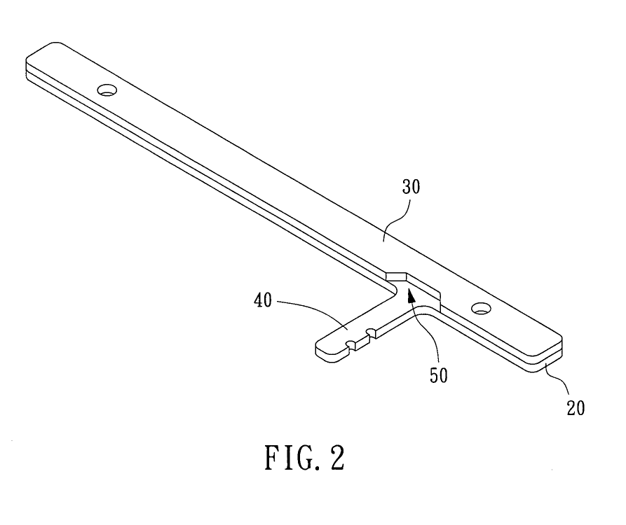

Please refer to FIG. 2, which is a schematic view of a FPC with reinforcement structure according to an exemplary embodiment of the invention. The FPC with reinforcement structure of FIG. 2 is comprises of a flexible printed circuitboard (FPC) 20 and a stiffener 30. The FPC 20 is configured with an extended part 40 extending outwardly from a side thereof. It is noted that the extended part 40 is also a flexible printed circuitboard that is integrally formed with the FPC 20. The formation of the FPC 20 and the extended part 40 can be a “T”-shaped or an “L”-shaped structure which is dependent upon actual requirement and thus is not limited thereby.

The stiffener 30 is stacking on a surface of the FPC 20 on the area excepting the extended part 40 in a manner that a height difference is formed between the surface of the stiffener 30 and that of the extended part 40. In this exemplary embodiment, the stiffener 30 can be a single-layered plate or a multi-layered plate, only if it is capable of enhance the rigidity of the FPC 20 for protecting the same from being damaged by any external force. In addition, there is a recess 50 formed on the stiffener 30 at the position corresponding to the extending direction of the extended part 40. In FIG. 2, the recess 50 is formed at the position corresponding to the turning points of the “T”-shaped or “L”-shaped structure while enabling the width of the recess 50 to be larger than that of the extended part 40.

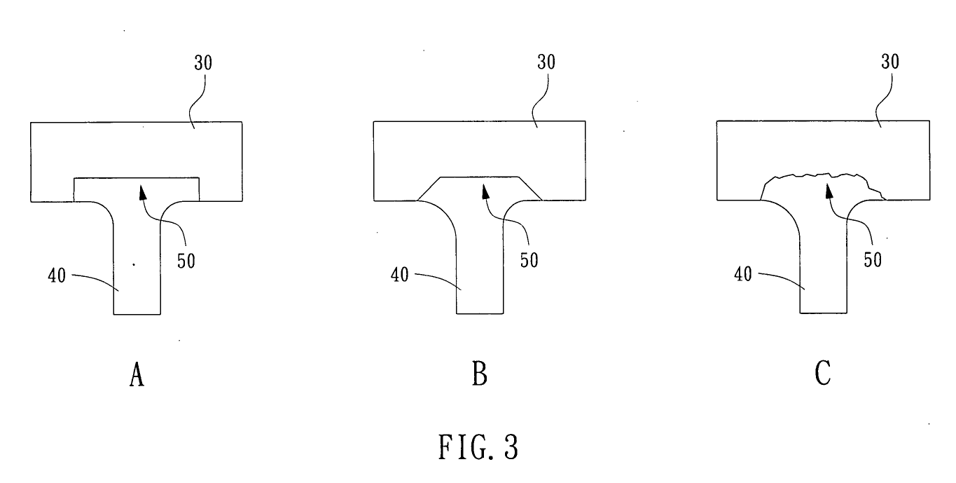

Please refer to FIG. 3, which shows a variety of recess formed on a FPC of the invention. As the recess 50 is formed on the stiffener 30 at a position corresponding to the extending of the extended part 40 in a manner that the opening of the recess 50 is opened toward the extending of the extended part 40, the recess 50 can be formed as a shape selected from the group consisting of: a “ [symbol] ”-shaped recess of two vertical sides as the “A” feature shown in FIG. 3, a “ [symbol] ”-shaped recess of two slanted sides as the “B” feature shown in FIG. 3, and recesses of any irregular shapes as the “C” feature shown in FIG. 3. It is noted that the shape of the recess 50 is dependent upon actual requirement that it is not limited by the embodiments shown in FIG. 3. In addition, the flexibility of the “T”-shaped or “L”-shaped structure is increased with the width of the opening of the recess 50 so that a recess 50 with comparatively large opening is able to reduce the stress concentration happening at the turning points of the “T”-shaped or “L”-shaped structure due to the reinforcement of the FPC 20 and thus prevent the extended part 40 from breaking off from the FPC 20.

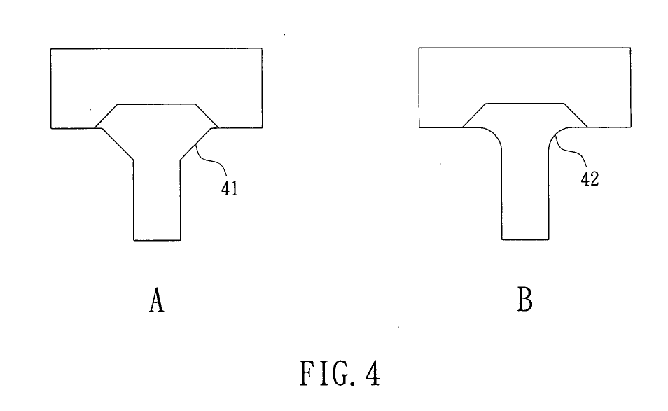

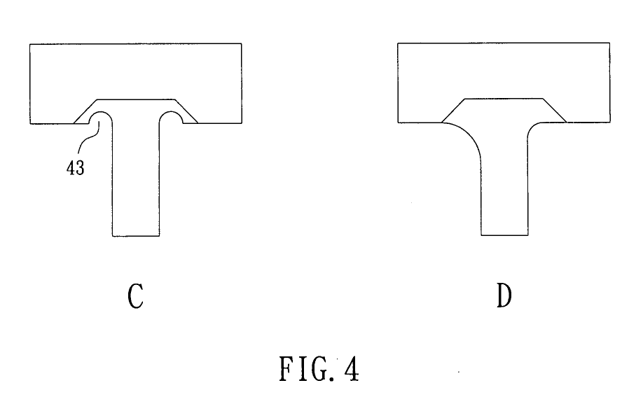

Please refer to FIG. 4, which shows a variety of chamfer design used in a FPC of the invention. Also for reducing stress concentration, two chamfers are formed at interfaces connecting the FPC 20 and two sides of the extended part 40 respectively. In FIG. 4, the chamfer can be slanted to be profiled as a slanted line 41 as the “A” feature shown in FIG. 4, or can be rounded to be profiled as an arc 42 as the “B” feature shown in FIG. 4, or can be a caved-in 43 as the one shown in the “C” feature of FIG. 4. In an exemplary embodiment of the invention, the two chamfers can even be slanted with angles that are not equal to each other, as those shown in the “D” feature of FIG. 4.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A flexible printed circuitboard (FPC) with reinforcement structure, comprising:
a flexible printed circuitboard (FPC), having an extended part at a side thereof; and
an a stiffener, stacking on a surface of the FPC on the area excepting the extended part while configuring a recess on the stiffener at the position thereof corresponding to the extending direction of the extended part.

2. The FPC of claim 1, wherein the stiffener is a board selected from the group consisting of a single-layered plate and a multi-layered plate.

3. The FPC of claim 1, wherein a height difference is formed between the the stiffener and the extended part.

4. The FPC of claim 1, wherein the recess is formed as a shape selected from the group consisting of: a “ [symbol] ”-shaped recess of two vertical sides, a “ [symbol] ”-shaped recess of two slanted sides, and a recess of any irregular shapes.

5. The FPC of claim 1, wherein two chamfers are formed at interfaces connecting the FPC and two sides of the extended part respectively.

6. The FPC of claim 5, wherein the two chamfers is formed in a manner selected from the group consisting of: the two chamfers are formed with angles that are equal to each other, and the chamfers are formed with angles that are not equal to each other.

7. The FPC of claim 5, wherein each of the two chamfer is rounded.

8. The FPC of claim 5, wherein each of the two chamfer is slanted.

9. The FPC of claim 1, wherein the width of the opening of the recess is larger than the width of the extended part.
